(19) United States
(12) Patent Application Publication
(10) Pub. No.: US 2008/0295885 A1
(43) Pub. Date: Dec. 4, 2008

(54) Thick Crystalline Silicon Film On Large Substrates for Solar Applications

(76) Inventor: Shing Man Lee, Fremont, CA (US)

Correspondence Address: DAVIS WRIGHT TREMAINE LLP, 505 MONTGOMERY STREET, SUITE 800, SAN FRANCISCO, CA, 94111, US

(21) Appl. No.: 12/102,775

(22) Filed: Apr. 14, 2008

Related U.S. Application Data
(60) Provisional application No. 60/932,211, filed on May 30, 2007.
(60) Provisional application No. 60/932,210, filed on May 30, 2007.
(60) Provisional application No. 60/932,234, filed on May 30, 2007.
(60) Provisional application No. 60/933,880, filed on Jun. 8, 2007.
(60) Provisional application No. 60/937,518, filed on Jun. 27, 2007.
(60) Provisional application No. 60/964,185, filed on Aug. 8, 2007.

(51) Int. Cl. H01L 31/0216; B05D 5/12

(52) U.S. Cl. 136/256; 427/74

(57) ABSTRACT

An apparatus for converting sunlight to electricity comprises a sheet of soda lime glass having a softening point not exceeding 600° C. and a layer of crystalline silicon over said sheet of soda lime glass. The layer has a thickness not less than about 5 microns and grains with grain size not less than about 100 microns. A method for making a device for converting sunlight to electricity comprises forming a film on a soda lime glass substrate, dispersing silicon powder onto the film and pressing a surface onto the silicon powder to form a layer of silicon powder on said film. The substrate and film are heated from below to a temperature so that the soda lime glass substrate softens. While the substrate is in a softened state, the silicon powder layer is heated by scanning a line focus laser beam or an elongated heater strip over a spatial sequence of adjacent elongated zones of the silicon powder consecutively so that the silicon powder in each of the zones melts and recrystallizes consecutively to form a layer of crystalline silicon with a thickness in the range of 5 to 100 micron over said film. Preferably the laser beam or heater strip scans and heats a triangular area of the layer of silicon powder, where the area has an apex leading said scan area during scanning.

### CROSS-REFERENCE TO RELATED APPLICATIONS

The present application claims priority to the following six (6) provisional applications which are incorporated herein in their entireties by this reference:

U.S. Provisional Application entitled “High Throughput Laser Assisted Deposition of Thick Crystalline Silicon Films on Large Substrates,” Application No. 60/932,211, filed May 30, 2007 by Shing Man Lee.

U.S. Provisional Application entitled “Methods of Making Highly Efficient Solar Panels at Low Cost,” Application No. 60/932,210, filed May 30, 2007, by Shing Man Lee.

U.S. Provisional Application entitled “Deposition of Thick Crystalline Silicon Films on Large Substrates,” Application No. 60/932,234, filed May 30, 2007, by Shing Man Lee.

U.S. Provisional Application entitled “High Temperature Silicon Processes on Large Substrates,” Application No. 60/933,880, filed Jun. 8, 2007 by Shing Man Lee.

U.S. Provisional Application entitled “Methods of Making Substantially Single Crystalline Film Using Zone-Melt Re—Crystallization,” Application No. 60/937,518, filed Jun. 27, 2007, by Shing Man Lee.

U.S. Provisional Application entitled “Aerosol Deposition of Thick Crystalline Silicon Films and Texturing Processes on Large Substrates,” Application No. 60/964,185, filed Aug. 8, 2007, filed by Shing Man Lee.

### BACKGROUND

Solar power has the potential of supplying endless energy. Although solar energy is free, but the cost to harvest it is still very high compared to conventional coal, petroleum, natural gas and nuclear energy. The demand on solar panels skyrocketed in recent years.

Recently there has been much work done to ‘reduce the solar power cost while keeping the efficiency high. In the context of solar power the efficiency is referred to the conversion efficiency from optical power from the sun to electrical power. The Moore's law equivalent on solar power states that price per watt peak power ($/Wₚ) drops by 19% with each doubling in manufacturing capacity. This reduction is much slower than the integrated circuit (IC) industry. The reasons for such slow price reduction are mainly attributed to the high cost of raw materials and complicated processes. To date, over 90% solar panels are made from silicon. About 50% of the cost for crystalline solar panels is just for the silicon wafers. The demand on solar panels created a silicon wafer shortage in recent years. Conventional silicon solar cell derives from the IC industry. To reduce cost is use thinner wafers, say from 380 to 200 microns but larger wafers (4″ to 6″), use lower grade silicon by sacrificing efficiency and improve process efficiency. Due to the lack of differentiation, these improvements are too slow to satisfy the market demand. Therefore, most of the solar panel companies have yet to turn a substantial profit.

It has been recognized that thin film solar panels can reduce costs in $/Wₚ because of the small amount of raw material usage, suitability for panel size process, and beyond instead as opposed to wafer size. Some of the lowest $/W panels are made of CaTe and CuInGaSe₂ (CIGS) and amorphous silicon (a-Si). However the cost of ownership for such systems is actually higher because: (1) Lower efficiency means higher installation cost, slower return on investment due to limited roof space; (2) Shorter lifetime and (3) unproven reliability. Therefore, they are still immature technologies and cost benefit, efficiency, and reliability are not yet established. It is highly questionable that they can improve efficiency and reliability at low price.

One well-established thin film solar cell process technology is the same as that used in high definition liquid crystal display technologies. Typically a Plasma Enhanced Chemical Vapor Deposition (PECVD) process is used to deposit amorphous silicon with approximately 1 μm thickness on a glass substrate. However a-Si solar cell efficiency is low due the high material defect density and thin layer. a-Si solar panels degrade as soon as they are exposed to light due to the Staebler-Wronski effect. Another major problem with thin silicon cells is slow growth rate. The growth rates for common techniques such as PECVD, Physical Vapor Deposition (PVD), and sputtering are less than 1 nm/sec. It takes more than 16 minutes to grow a 1 μm layer and another five hours of annealing time at 500° C. to remove the hydrogen residuals. Therefore, such processes are they are very capital intensive to get to high throughput production which is required for mass production of solar panels.

It is desirable to use crystalline silicon for solar cells because grain boundaries increase serial resistance and reduce quantum efficiency. Quantum efficiency is a measure of the amount of current generated from each photon of light. The a-Si was re-crystallized with the zone melt re-crystallization (ZMR) technique to form a crystalline layer.¹ This technique has been used extensively for high definition liquid crystal displays where the film is very thin (<500 nm). However, it is not suitable for solar cell applications because of the thin silicon layer. It would take a much thicker silicon film to make efficient solar panels. A 25 μm thick silicon film absorbs only 80% of in-band solar energy and 50 μm thickness gets to the 90% mark. Hard wire CVD offers a considerably higher growth rate (2-10 nm/sec). However, it is still too slow and it introduces too much impurity into silicon layer.² High growth rate iodine transport has been demonstrated as a means for fast silicon growth rate of 5 um/min and it has gained considerable attention in recent years.³ Sintering techniques, which are commonly used in making ceramics, have been used for making silicon films. The small grain size makes them undesirable. Without exception, all thick silicon film growth techniques require high temperature substrates such as silicon wafer, sapphire or high temperature glass substrate. These substrates are very expensive. Therefore, no cost saving can be realized with these approaches.

It is clear that none of the present process technologies are suitable for solar cell manufacturing. It is, therefore, highly desirable to have a process technology for fast growing of over 5 μm thick (e.g. 5-100 μm) silicon solar cells at low cost.

### SUMMARY OF THE INVENTION

In one embodiment of the invention, an apparatus for converting sunlight to electricity comprises a sheet of soda lime glass having a softening point not exceeding 600° C. and a layer of crystalline silicon over said sheet of soda lime glass. The layer has a thickness not less than about 5 microns and grains with grain size not less than about 100 microns.

In another embodiment of the invention, a method for making a device for converting sunlight to electricity comprises forming a film on a soda lime glass substrate, dispersing silicon powder onto the film and pressing a surface onto the silicon powder to form a layer of silicon powder on said film. The substrate and film are heated from below to a temperature so that the soda lime glass substrate softens. While the substrate is in a softened state, the silicon powder layer is heated by scanning a line focus laser beam or an elongated heater strip over a spatial sequence of adjacent elongated zones of the silicon powder consecutively so that the silicon powder in each of the zones melts and recrystallizes consecutively to form a layer of crystalline silicon with a thickness in the range of 5 to 100 micron over said film.

In still another embodiment of the invention, a method for making a device for converting sunlight to electricity comprises forming a film on a soda lime glass substrate, dispersing silicon powder onto the film and pressing a flat surface onto the silicon powder to form a layer of silicon powder on said film. The substrate and film are heated from below to a temperature so that the soda lime glass substrate softens. While the substrate is in a softened state, the silicon powder layer is heated by scanning a line focus scanning laser beam or a heater strip over a spatial sequence of adjacent zones of the silicon powder consecutively so that the silicon powder in each of the zones melts and recrystallizes consecutively to form a layer of crystalline silicon with a thickness in the range of 5 to 100 micron over said film. The laser beam or heater strip scans and heats a triangular area of the layer of silicon powder, where the area has an apex leading said scan area during scanning.

According to another embodiment of the invention, an epitaxial silicon layer may also be grown onto soda lime glass substrate using iodine transport for dispersing silicon powder.

All patents, patent applications, articles, books, specifications, other publications, documents and things referenced herein are hereby incorporated herein by this reference in their entirety for all purposes. To the extent of any inconsistency or conflict in the definition or use of a term between any of the incorporated publications, documents or things and the text of the present document, the definition or use of the term in the present document shall prevail.

### BRIEF DESCRIPTION OF THE DRAWINGS

FIG. 1 is a flow chart illustrating a thick silicon film fabrication process flow.

FIG. 2 is a cross-sectional view of a solar cell structure.

FIG. 3 is a cross-sectional view of a substrate carrier and heater assembly.

FIGS. 4(a), 4(b) and 4(c) are cross-sectional views of a glass substrate in a holder undergoing a silicon powder dispensing process. FIG. 4(a) illustrates a process of pouring the right amount of silicon powder on top of substrate. FIG. 4 (b) illustrates a process of aligning a cover with imprint pattern with the substrate. FIG. 4 (c) illustrates a process of pressing the cover down with uniform force to form a flat and uniform powder film.

FIG. 5 is a partly cross-sectional view and partly schematic view of silicon powder on top of a glass substrate in a holder undergoing a laser annealing process using laser bar and cylindrical lens, where a two dimensional grid pattern has been formed in the powder layer.

FIG. 6 is a perspective view of silicon powder on top of a glass substrate in a holder undergoing a laser annealing process using laser bar and cylindrical lens, where a two dimensional grid pattern has not been formed in the powder layer.

FIG. 7 is a partly cross-sectional view and partly schematic view of the scheme of FIG. 6 to illustrate the melt zone formed in the laser annealing process.

FIG. 8 is a schematic view of a teeth pattern on a cover used for forming the two dimensional grid pattern illustrated in FIG. 6 when the cover is pressed against the silicon powder layer.

FIG. 9 is a top view of a silicon powder on top of a glass substrate in a holder undergoing a laser annealing process using laser bar to illustrate a process for forming a single crystalline silicon layer for solar applications.

Identical components in this application are labeled by the same numerals.

### DETAILED DESCRIPTION OF EXEMPLARY EMBODIMENTS

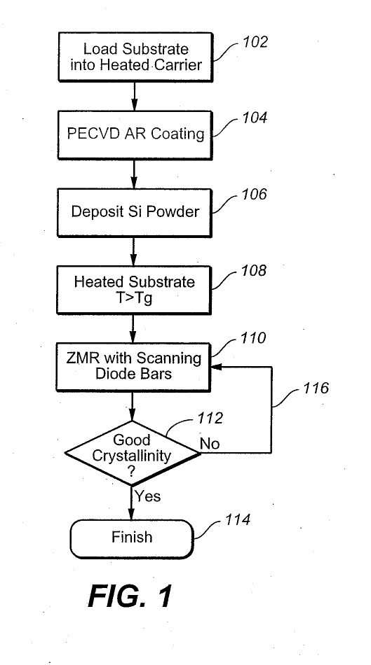

This invention discloses processes of making low cost, large scale, and high purity thick crystalline silicon film for solar cell. Thick silicon films (over 5 μm) are made on low temperature substrate. Soda lime glass (that is glass used in windows used in window of residential and commercial buildings) is of low cost and is widely available. A new process is used that combines substrate preparation, temperature control, use of silicon powder materials, and laser annealing to observe silicon thick films that is substantially crystalline. A schematic of the process flow is shown in FIG. 1.

A substrate is prepared and loaded onto a carrier (block 102). An anti-reflection (AR) coating is formed using the PECVD process (block 104). Silicon powder is then dispersed onto the AR coating (block 106). The carrier, substrate and the carrier are then heated to a temperature (e.g. 600° C.) greater than the softening point of the material of the substrate causing the substrate to soften (block 108). The silicon powder is then melted by means of a scanning laser diode bar or heater strip (block 110). As the silicon cools and recrystallizes, it is checked to determine whether it has good crystallinity (diamond 112). If it does, the fabrication continues with other processes such as forming pn junctions in the silicon layer for solar cells and electrical contacts for the cells (oblong 114). If not, the melting, cooling and recrystallization process is repeated until there is good crystallinity (feedback path 116). The crystalline silicon so formed has grains with grain size not less than about 100 microns.

The substrate comprises window glass, which is also called soda lime glass. According to “Encyclopedia Britannica—the Online Encyclopedia,” soda lime glass is the most common form of glass produced. It is composed of about 70 percent silica (silicon dioxide), 15 percent soda (sodium oxide), and 9 percent lime (calcium oxide), with much smaller amounts of various other compounds. The soda serves as a flux to lower the temperature at which the silica melts, and the lime acts as a stabilizer for the silica.

Crystallinity in diamond 112 may be determined by observing under an optical microscope the crystalline silicon layer that is formed and see if the grain size of the crystalline silicon is more than a certain size, such as 100 μm. Such processes are very suitable for solar cell applications where high efficiency and substantially low cost can be obtained. They are environmental friendly that use little chemicals and easily scaled to high volume production. The new processes are to improve making thick silicon films as an integral part of the reducing the cost and improve efficiency in solar panels. It is well suited or high volume manufacturing.

### Preparation of Substrate

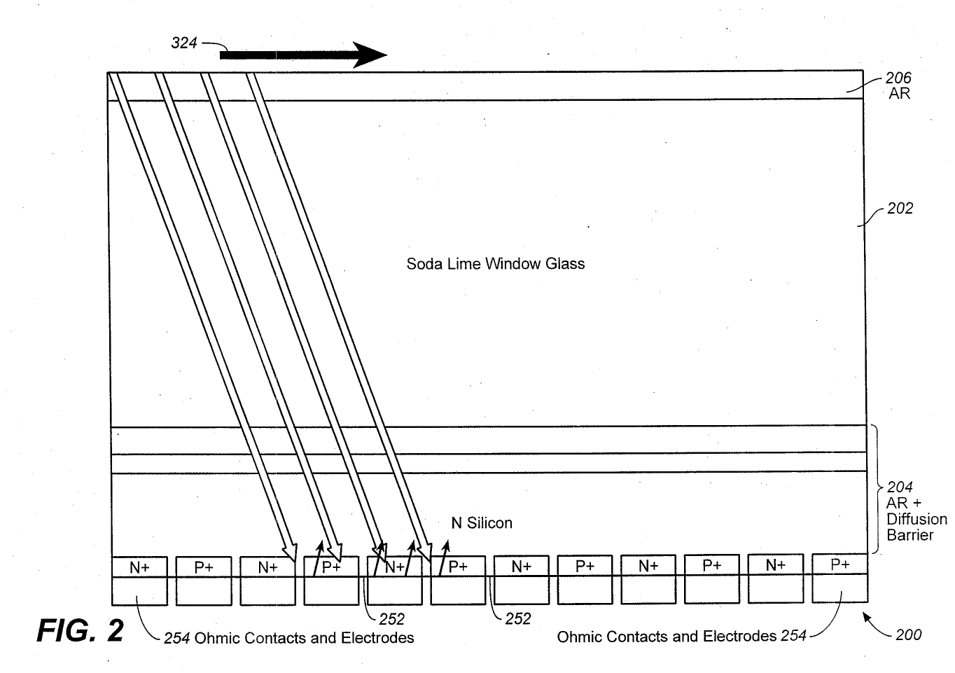

A solar cell structure 200 formed in the above described process is shown in FIG. 2. Without any limitations, the size of substrate is the same or can even be even much larger than a standard solar panel which is 0.8 m×1.6 m. High temperature diffusion barrier layers such as silicon nitride and silicon dioxide may be deposited onto the substrate first to keep the substrate impurity from diffusing and reacting with the silicon deposited on top of the barriers. Preferably the diffusion barrier layers can also have anti-reflection properties. Thus the substrate 202 is first prepared by depositing an Anti-reflection (AR) coating 204, optionally and without any limitations a quarter wavelength silicon nitride at the center of the optical spectrum. This layer 204 also acts as a diffusion barrier layer to prevent impurity from substrate, such as sodium or tin, to diffuse to the silicon layer to be formed. Without any limitation, a thin silicon dioxide layer with a thickness in the range 10 nm to 1,000 nm is deposited on top to prevent nitrogen from diffusing into the subsequent silicon layer. Optionally and without limitations, another AR coating 206 can be applied to the other side of the glass to gather more photons on the silicon layer. This AR coating can improve photon collection efficiency by 4%. It is understood by those skilled in the art that other materials or combination of materials can be used to achieve the function of the AR coating and diffusion barrier layers. The materials mentioned herein are only by way of example and should not pose any limitation on the generality of the invention.

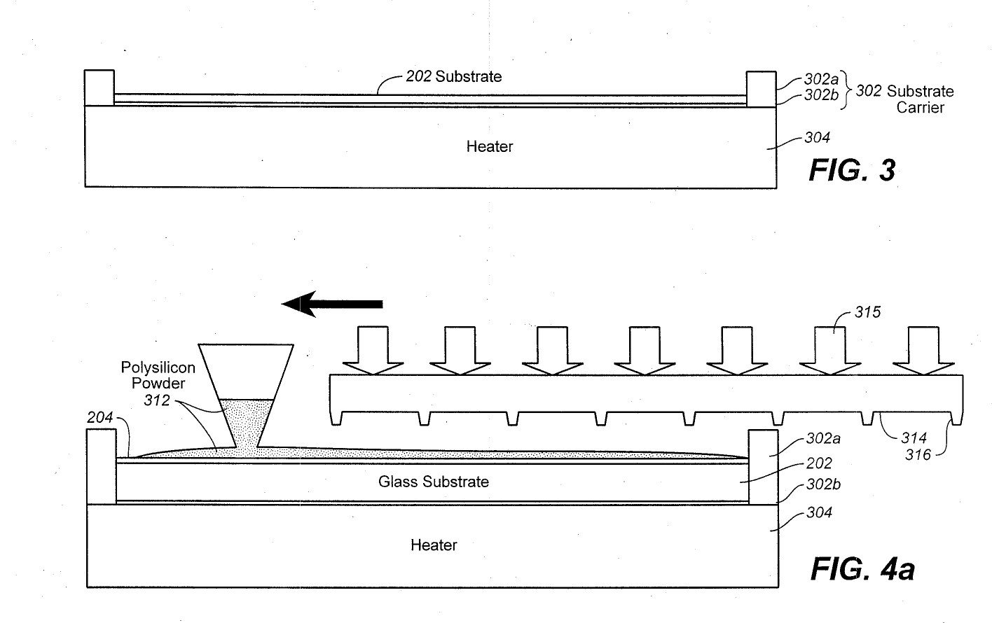

High temperature processes are very desirable in the growth of crystalline films without using the expensive high temperature substrates such as silicon, sapphire, high temperature borosilicate glasses, graphite, etc. I propose to uniformly heat the substrate (which can be low cost glass such as window glass) above the glass transition temperature. At this temperature range, the substrate softens and thus sustains large local heating without breaking the substrate. As an example of implementing this approach, the substrate is put into a heated carrier 302 as shown in FIG. 3, that can be used for moving the substrate through different processes and control the substrate temperature. Through the carrier, the substrate is heated by means of heater 304 to over the glass softening point, or transition temperature, i.e. 560° C. for soda lime glass. The substrate becomes soft and the carrier 302 keeps it from deforming. The guard 302a around the holder 302b provides a way to secure the substrate 202 and keep the substrate and materials deposited on top in shape at high temperature.

### Preparation of Polysilicon

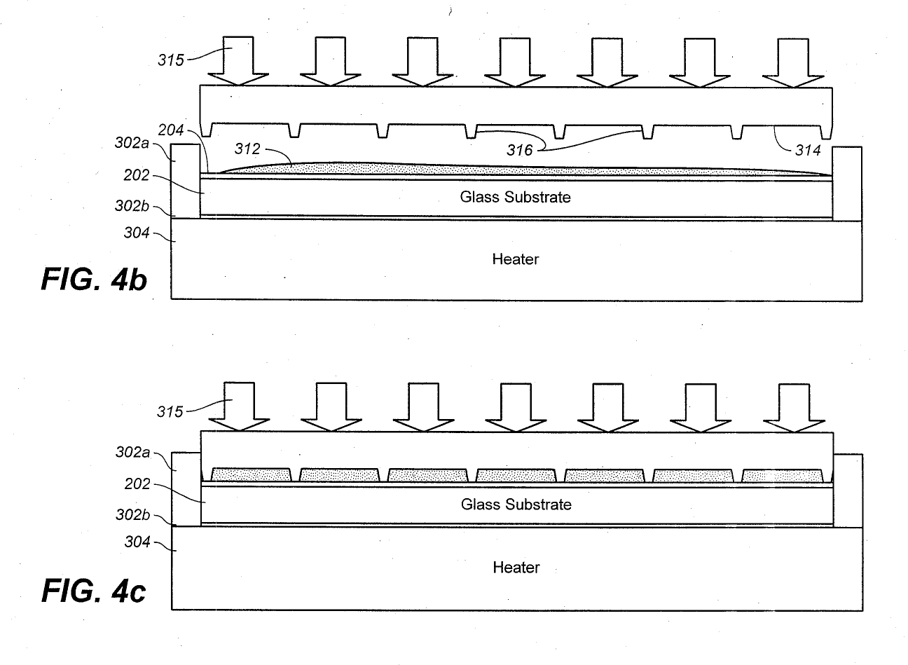

A uniform layer of polysilicon powder 312 is applied to surface with the grain size substantially less than the required layer thickness. For a 20 μm thick silicon layer, the powder size of the powder is smaller than 10 μm. The small powder size makes the silicon densely packed and hence more uniform. The guard 302a around the substrate keeps the powder from spilling out. The amount of silicon powder deposited is controlled to achieve the required thickness plus a little over head for loss during the dispersion process and uneven thickness. As shown in FIG. 4(a), one way of dispersing the silicon powder is to pour the powder onto the AR film 204 on top of the substrate. Due to porous nature of the powder, the power thickness is thicker than that required to achieve a particular silicon film thickness. One way to make it uniform, without any limitation, is to use an imprint technique as shown in FIGS. 4(a)-4(c). After a desired amount of powder has been poured onto the film and substrate (FIG. 4(a)), a mostly flat cover or base 314 will align with the substrate carrier (FIG. 4b). When a uniform force 315 is applied to the cover, it will make a flat powder film on the substrate (FIG. 4(c)).

Extra caution is taken to minimize the amount of dust when dispensing power. It can cause the loss of silicon material and damage the vacuum pump systems. It is desirable to reduce or prevent the spreading of the silicon powder to areas other than the substrate. One example is to slide the cover in as the powder is dispensed on the film and substrate as shown in FIG. 4(a). Another example is to dispense the power in an enclosed volume. After dispensing, the dispensing apparatus such as bag, tubing, funnels, etc. can be moved out of way for the cover to clamp down on the substrate.

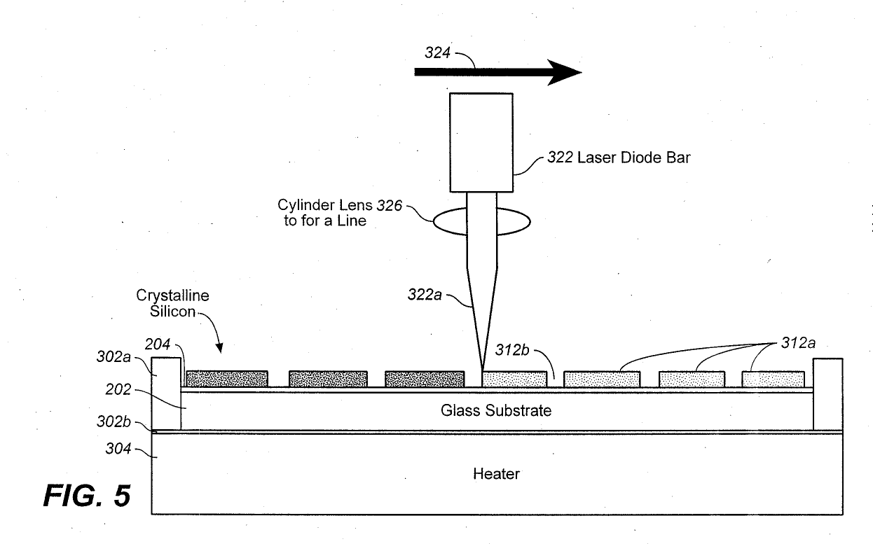

Another difficulty is to make a uniform film on a substrate larger than solar panels. However, silicon film uniformity through the substrate is not critical in solar cell applications. The film should be greater than a minimum thickness about 20 μm for higher solar conversion efficiency. There are many ways to ensure that a minimum thickness is achieved. One of simplest way is to put teeth patterns 316 on the cover as shown in FIGS. 4(a)-4(c). When a generous amount of silicon powder 312 is applied followed by some smoothing action such as vibration on the substrate, the substrate will be covered with silicon powder with more than the minimal thickness. When the teeth of patterns 316 touch the substrate due the uneven force applied on a large substrate, the cover 314 would not move any further, thus ensuring that the silicon film will have an acceptable minimum thickness. In general, the teeth pattern is in general a two dimensional array structures that serve other useful purpose such as cell definition and stress relief pattern discussed below. The resulting pattern of blocks of silicon powder 312a in the silicon powder layer is illustrated in FIG. 5, with trenches 312b there between.

The silicon powder is made of electronic grade silicon commonly available. The polysilicon feedstock is generally granular from the Fluidized Bed process for electronic grade silicon. One of the byproduct is this process is a large quantity of pure silicon fine powder. Although they are electronic grade silicon, they are normally discarded for they cannot be used in making ingots. They are also sold to the tool making industries. The current invention can use them directly in solar cell applications for much lower cost. Another way to obtain silicon powder is to use the regular granular polysilicon feedstock from many silicon producers. The polysilicon is to be dipped in hydrofluoric acid (HF) acid to remove any native oxide formed on the surface. If the polysilicon particles is larger than a desired size, such as larger than 10 μm, a number of techniques such crushing and quenching can be used to further reduce the powder size.

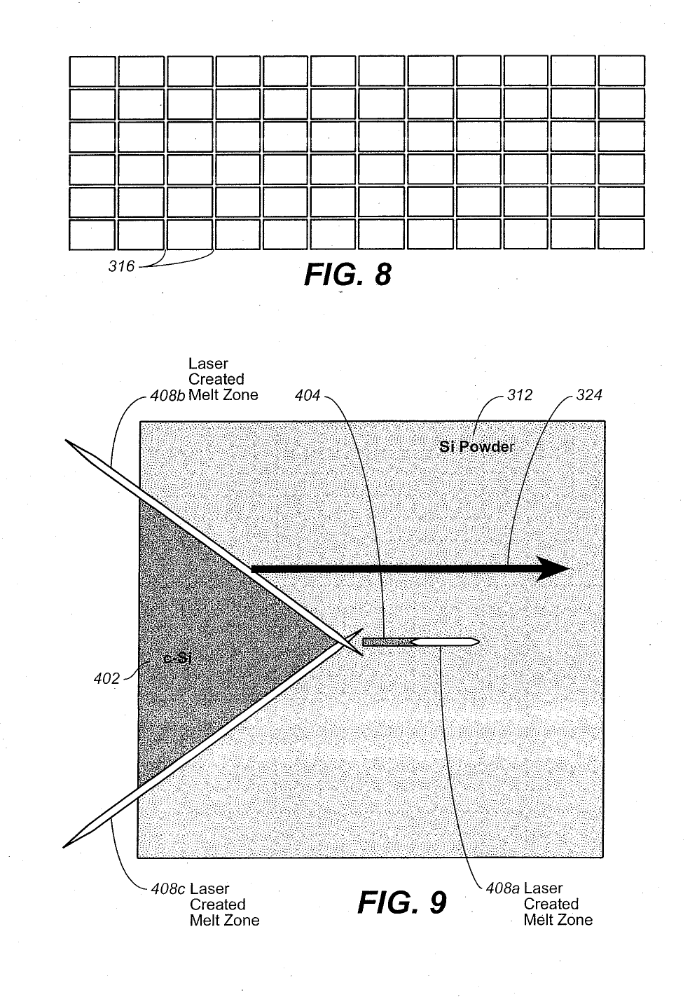

When thick films are deposited on foreign substrates, there will be a residual stress that may cause the film to crack. To address this issue, a checkered pattern 312a of silicon may be formed on the substrate as described above also with a slot cooling of the finished panel below Tg. The checkered pattern will also be useful for defining individual solar cell on the panels. In conventional solar panels, the definition of the cell is by the wafer size. In the thin film solar cell, laser scribing often used to define the cell. However, it is harder to use laser scribing for a thick film. The teeth pattern 316 and the ridges thereof on the cover 314 on FIGS. 4(a)-4(c) can be made into checkered or grid shaped patterns as shown in FIG. 8. As shown in FIG. 8, the ridges (shown as white lines on a dark background, which together form the pattern 316) form a two dimensional raised grid structure. Then when the cover is pressed onto the silicon powder, it not only flattens the powder but also defines a two dimensional array of raised areas 312a with trenches 312b between adjacent areas formed on a surface of said layer of silicon powder for stress relief and solar cell definition. This is illustrated in FIG. 5. In the boundary or trench regions 312b of the checker patterns 312a, there will be no silicon, hence the cells can operate independently.

The substrate with the carrier is transferred back to the PECVD chamber to deposit protective coating for subsequent processing. For example, a thin layer (20 nm) of amorphous-silicon is deposited to cover or encapsulate the silicon powder, to keep the powder from moving and to prevent the powder from reacting with ambient or other chemical species see FIG. 1. Once encapsulated, the substrate is moved to ambient environment for further processing.

### Laser Annealing

Laser annealing can turn a-Si thin film into crystalline ones. However, thermal budget for thick films is much higher when the silicon film thickness moves from less than a micron to a value between 5 and 100 μm, such as 30 μm or a higher thickness. A much higher laser power (three order magnitude increase) is needed and local annealing creates thermal stress that may break the substrate. High power (thousands of watts) and short wavelength (<360 nm) laser, which the silicon layer absorb efficiently and very high power (>2 kW), are not commercially available and prohibitively expensive.

The above problems are solved by pre-heating with heater 304 the substrate 202 (and hence also film 204) to above the softening point or glass transition temperature and then use ultra high power continuous wave (CW) near infrared laser annealing to melt the silicon powder 312 in each of the areas 312a and create continuous crystalline silicon film in such areas. The soda lime glass is the most common low cost glass. Above glass transition temperature, substrate will be softening that thermal stress will not break the substrate. Silicon becomes very absorptive above 300° C. to 400° C. for wavelength range from UV to IR such as 10.6 μm CO₂ laser, whereas it is only highly absorbing below 360 nm at room temperature.

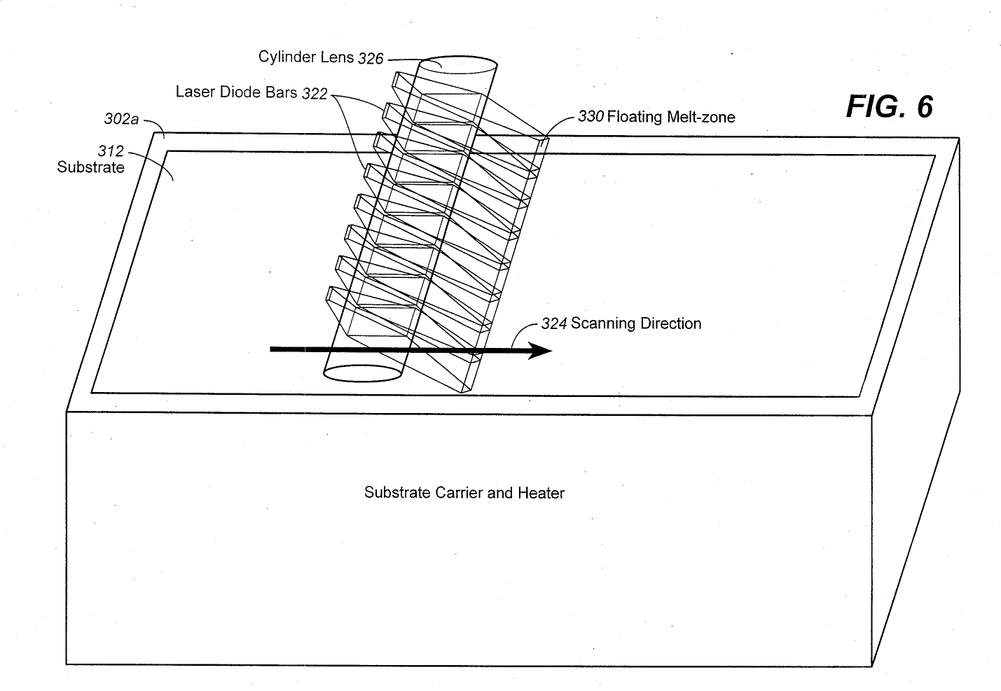

At the elevated temperature, high power laser bars 322 can be used to form a line to scan laser beams 322a along direction 324 across the substrate 202 to create local heating from the top of the microcrystalline silicon powder 312 as shown in FIG. 5. The laser beams are focused to an elongated area of the silicon powder layer 312 by means of cylindrical lens 326. The silicon powder 312 in the area is melted by the laser beams and the elongated melt zone 330 can be as wide, (length of the elongated melt zone, perpendicular to plane of paper in FIG. 5) as the whole substrate which is at least the size of a typical solar panel, 0.8 m×1.6 m. Zone 330 is shown in FIG. 6. Laser bars have very high power. Typical laser diode bar wall plug efficiency is about 35% with power density over 200 W/cm. Therefore, one can deliver many thousands of Watts of power onto the silicon. The most efficient lasers are AlGaAs lasers with wavelengths around 780 nm or 980 nm. Such wavelengths can be absorbed efficiently at an elevated temperature. Thus, they can be very effective in delivering heat to the silicon powder surface. The laser light heats up the first 1 um silicon at the top of the silicon powder surface. The high laser power will create a melt zone on the surface.

Thus, the laser beams 322a melt a spatial sequence of adjacent elongated zones of the silicon powder consecutively so that the silicon powder in each of the zones melts and recrystallizes consecutively to form a layer of crystalline silicon with a thickness in the range of 5 to 100 micron over said film. This occurs in the silicon powder 312 layer in each of the areas 312a. In another embodiment the layer of crystalline silicon may be 30-100 μm thick.

As the laser scans through the film surface of the powder in each of the areas 312a, a multi-crystalline silicon film forms in the area. The grain size largely depends on the layer geometry, heating power, nucleation sites and how it cools. Crystal grows along the direction of temperature gradient. In conventional annealing of very thin films, the heat dissipates mostly to the bottom of the silicon layer at the interfaces with the substrate, resulting grain sizes ranged a few microns wide and millimeters long.

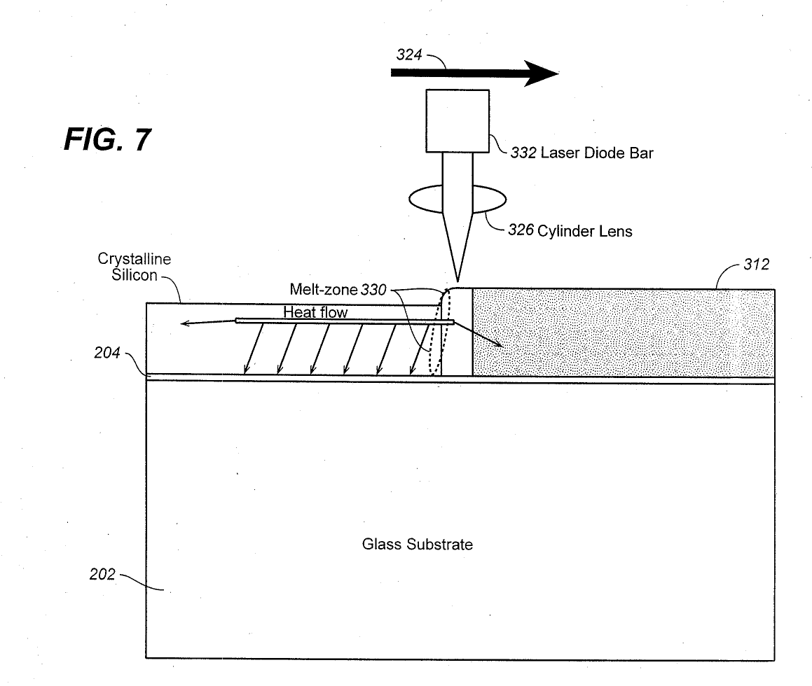

One embodiment of this invention is directed to a low cost thick silicon film growth technique with much bigger grain sizes. The schematic is shown in FIG. 6. Trenches 312b have been omitted in FIG. 6 to simplify the figure; alternatively, FIGS. 6 and 7 illustrate an embodiment where the cover 314 is not provided with pattern 316, so that the trenches 312b are not formed. The ZMR method have been enhanced with a few novel techniques:
1) Soda lime glass substrates are put into a carrier where the processing temperature can be higher than the glass softening point or transition temperature as shown in FIG. 3.
   a) Soften the substrate so that it does not break due to high power local heating.
   b) Save valuable laser power.
   c) Low substrate requirement that all mechanical tolerance are built into the carrier for subsequent fabrication steps
   d) Above glass transition temperature deposition of a hetero film also have the benefits of great reduction of the thermal induced stress after the formation of film, i.e., no built in stress from silicon melting point to just below Tg.
   e) The flatness of the substrates depends mainly on the substrate carrier at such elevated temperature. This is further reduces the requirements for the substrate, reducing material cost.
2) Polysilicon powder is used as the base material instead of using traditional film deposition techniques:
   a) It has a very high growth rate, literally pouring powder onto the substrate.
   b) Clean process step. It needs just heat, no additional chemical for film formation.
3) Low heating requirement
   a) Si powder heat conductivity is much smaller then silicon film, powder can be heated to melting point before heat loss due to conduction, i.e., need less power than heating a solid film to create a melt zone.
   b) Si powder has very high surface energy that it needs less laser energy to melt the silicon powder.
4) Large grain size
   a) Lateral epitaxy dominates in thick film as heat conduction mainly on the film against the scanning direction as shown in FIG. 7. Also shown was the re-crystallized film on the left side of the scanning beam. This film is thinner than the layer of porous powder on the right side of the scanning beam.
   b) The melt zone is vertically tilted because of the silicon powder is less conductive in such a way that crystallization also occur from top to bottom, further suppressing nucleation from the substrate.
5) High flatness
   a) Zone-melting re-crystallization techniques produce very flat film surfaces.

The polycrystalline powder 312 can act as the seed to start the crystal re-growth process. Because the random nature of the poly crystalline seeds, the final grain sizes is elongated along the scanning directions. Grain boundaries induce internal resistance and lower quantum efficiency. However, the grain size is much bigger than thickness of the film which is on the order of 30 um. At such low defect density, the quantum efficiency of the film is very close to that of the crystalline silicon. For optimal solar cell operation, the inter-digital fingers of the PN junctions 252 (see FIG. 2) need to be perpendicular to the scan direction 324. The photo-generated electron and hole pairs generated need to get to the respective electrical contact region 254 without crossing large number of grain boundaries.

In one implementation, {100} silicon film cover the whole substrate can be obtained by creating an {100} seed silicon film first. One can used the fact that the {100} melting point is a little higher than those of other orientations. When the crystal melts and has time to re-crystallize slowly, {100} silicon seeds can be formed by repeat scanning at the right power level to slow the re-crystallization speed. After the seeds are formed, scanning the heat source across the panel generates a thick crystalline silicon film.

This annealing process is most suitably performed in vacuum or a reduced pressure inert gas such as argon. Therefore, a dense film without voids can be obtained. Furthermore, the high temperature process that melts the silicon will also form a very smooth surface. Lastly, cutting off the heat convection can reduce the heat load for annealing and much lower chamber temperature. Lower temperature reduces the heat sink requirement for the laser diode bars and the power loss on the collimating lens.

Diffusion barriers 204 are made of silicon nitride and silica (silicon dioxide) whose melting point is much higher than that of silicon. Diffusion barriers 204 can be a mixture of silicon nitride and silicon dioxide (formed by spraying or depositing both materials at the same time), or can comprise alternate layers of silicon nitride and silicon dioxide. It will effectively block high impurity diffusion from the substrate even at extremely high temperature during melt zone passes.

When a thick silicon film is deposited or formed on foreign substrate, there will be a residual stress that can cause the film to crack. One can address that issue by putting checkered patterns on the silicon powder layer as described above with a slow cooling of the finished panel to below Tg after annealing. The checkered pattern avoids stress build up to a point that breaks the silicon film. Slow cooling also gives time for the film to release stress as it cools. To further reduce stress, repeated annealing at decreasingly substrate temperatures can help reduce the stress completely.

The checkered pattern will also be useful for defining individual solar cell on the panels. In conventional solar panel, the definition of the cell is by the wafer size. In the thin film solar cell, laser scribing is often used to define the cell. However, it is much harder to use laser scribing for a thick film. The conventional approach will not work. The embodiments of the invention employ a number of ways to deal with such issue effectively:
1) Modify the teeth pattern on the cover on FIGS. 4(a)-4(c) into checkered patterns. The cell definition can be defined with the imprint technique as described above in reference to FIG. 8. In the region boundaries of the checkered patterns, there will be no silicon, hence the cell can operate independently.
2) The second method is to use a shadow mask during laser scanning across the substrate. This can be used in combination with controlling the laser power during the scan. The laser diode bar is well suited for such task.
3) The cell isolation structures 312a also help reduce the heat load due to conduction that the cells are much smaller than the whole substrate.

### High Throughput System

ZMR technique for growing a thick silicon film on low temperature substrate is implemented as follows.

When the heated mass that is the amount of silicon on top of substrate is very small, and the substrate is a very effective heat insulator, and only a very small amount of energy is needed for zone-melt re-crystallization techniques. For a typical panel of 1.4 m² with 30 um thick silicon film, it only takes 54 kJ to heat the silicon powder layer to the melting point. Using a 2000 W diode bars to form a line illumination across the whole panel as shown in FIG. 7, it takes about half of a minute to deliver the energy. Based on the typical 200 W/cm laser diode bar supplied by a number of vendors, one can as much as 16000 W across the 0.8 m width channel. Therefore, delivering the heat using the ZMR technique on the whole panel is entirely possible. The laser bars also have very long lifetimes, typically 10,000 hours and relative inexpensive (about $30/Watt). The cost of ownership will be very low. It have been demonstrated the crystalline silicon film can be formed even with 0.3 m/s scanning speed. This process makes it possible to deliver enough power to create an melt-zone across the entire substrate at a top speed of 0.3 m/sec. Therefore, it is possible to construct an annealing system to have a 1 panel/min. throughput, taken into account heat conduction out of the heating area.

I have described a novel process of depositing thick (>20 um) silicon film onto inexpensive substrate such as soda lime glass. The invention describes a technique that uses low temperature substrate (not exceeding 600° C.) in the process with very high local temperature which results from laser melting of the silicon powder. Laser annealing created a traveling melt zone to cause the silicon powder to re-crystallize. The use of silicon powder reduce the heat conduction out of the melt zone and reduced the amount of heat to melt the silicon so one can have a much smaller thermal budget. It uses just the right amount of silicon without any waste or by product as in the typical thin film deposition technology.

When used in the solar energy applications, it would have comparable efficiency and reliability as the crystalline solar panels without the high price tag. It uses as little as 3% of silicon to make thick silicon film on the flight. The panel size crystalline film makes possible combining cell and panel processing. The present invention can dramatically reduce the cost of making high efficiency solar panels.

Heater Strip

A heater strip such as graphite strip heater may be used instead of laser diode bars in the same manner as described above for melting the silicon powder. The heater temperature can be as high as 2000° C. and very high power. This process is best placed in a purge environment such as Ar to prevent the ambient react to with the silicon powder. The heater which is extends, without limitation, across the whole substrate (over 800 mm wide) is placed, without limitation, very close (within 1 mm) to the silicon film to effectively heat the silicon film through convection. The encapsulating film might break during the recrystallization and densification process. An Ar purge prevents unwanted impurity from getting into the film.

An alternative heating method is to have the heat in thermal contact with the film and that is within the scope of this invention also. Working in the purged environment using heat convection instead of conduction gives a better control on the heat transfer. Although heat conduction is more effective, it is difficult to keep the heater to damage the film while maintaining good thermal contact. The heat convection process provides a much better process control.

As the heater moves across the substrate, it will create a melt zone 330 in the silicon layer as before moving across the substrate. The melt zone from the top of silicon film cools mainly through lateral conduction on the silicon layer. As it cools, it forms a crystalline layer using the crystal formed previously as the seed and recrystallization move along with the heater movement as shown in FIG. 7. Such a re-crystallization process has been demonstrated on silicon substrate previously.

To further reduce the random orientation of the seed on polycrystalline powder, one can used the fact that the {100} melting point is a little higher than those of other orientations, as described in U.S. Pat. No. 7,169,690 which is incorporated herein in its entirety by reference. When the crystal melts and has time to re-crystallize slowly. By controlling the speed of the cooling rate, one can create a {100} silicon as the seed. {100} silicon film can be obtained using repeated scanning, where the power levels and scanning speed needs to be optimized.

Because of the close proximity of the heater to the film, the heater might contaminate the surface of the encapsulating film. A thermal oxide will form on the top of silicon as soon as it moves out of the chamber. This layer surface is contaminated due to the particles generated by the high power heater strip heater strip. A HF etch and cleaning step is needed to remove native oxide layer for subsequent process.

Iodine Transport Deposition

Iodine transport purification and growth of polysilicon for growing silicon films on high temperature substrates is described in U.S. Pat. No. 6,281,0983. In another embodiment, thick layers of silicon films are instead grown on soda lime glass substrates which are low temperature substrates, using the fast deposition process of iodine transport purification and growth as described in U.S. Pat. No. 6,281,0983. The soda lime glass substrate may be heated with the heater assembly 304 in the manner illustrated above. The soda lime glass becomes a viscous solution and the holder 302 will keep the glass from deforming or leaking. The barrier layer 204 is flowing on the top, still acting as protective film. The deposition will continue on top of the molten glass. At the desirable polysilicon thickness, the temperature of the substrate is lowered, then the deposition process stops, and the glass solidifies again. Because of the high growth rate for iodine transport growth, a 30 um (or thicker) thick polysilicon film can be deposited in 5 minutes. Using the processes disclosed above, such polycrystalline silicon film can be re-grown into crystalline films. The crystalline film on large substrate can then be used for solar cell/panel applications.

High temperature processes are very desirable in the growth of crystalline films without using the expensive high temperature substrate such as silicon, sapphire, high temperature borosilicate glasses, graphite, etc. I propose to uniformly heat the substrate (which can be low cost soda lime glass such as window glass as described above) above the glass transition temperature. At this temperature range, the substrate softens and thus sustains large local heating without breaking the substrate.

Fast Growth of Polysilicon

The iodine transport technique is just one example of using high temperature processing on large soda lime glass substrates. Without any limitations, the technique disclosed in this invention can be applied to all high temperature process using the heated substrate. Other high temperature semiconductor processes such as diffusion, oxidation, getter, annealing, and metallization can similarly be applied on silicon on large substrate using the current invention.

The thick polysilicon film obtained from the above process can be made into crystalline layer with very large grain size using the annealing processes described above.

Single Crystalline Silicon Layer

Based on the result of Park et. al., “CW Laser Crystallization of Amorphous Silicon; Dependence of Amorphous Silicon Thickness and Pattern Width on the Grain Size”, Thin Solid Films, pgs. 511-512, and 243-247 (2006), it is clear that nucleation sites mainly come from the sides and bottom when the melt zone crystallize first. One embodiment of this invention is directed to a method to make silicon film into a large mostly single crystalline silicon film with (100) orientation.

The use of a heated substrate to above the glass transition temperature of the substrate serves two important the purposes. The first is heating the silicon so that it efficiently absorbs light from UV to IR. It enables the use of IR laser as a heat source which can prove the power and low cost of ownership for a production system. The second purpose is to soften the substrates so it can stand the huge heat induced stress during the annealing of thick films. Due to the long melt zone, the initial nucleation sites do not have any correlation between each other. This will result in elongated crystal grain boundaries along the scanning directions.

As described above in reference to FIG. 6, laser diode bars 322 to form a line on the substrate to create the melted zone. As the zone scanned across the substrate, it creates crystalline films. The diode bars are very high power and low cost compared to other type of UV lasers typically needed for ZMR. This embodiment of this invention enables larger nearly single crystalline to be created using angular melt zone. The setup is similar to that described above. It starts out with a silicon material on top of substrates, either in poly, amorphous, or powder forms. Because the diode bars are discrete devices, they can be configure in ways that is advantageous to us.

The melted zone is divided into two parts, namely seed generation and recrystallization. The seed generation part is an elongated melt zone oriented along the scanning direction.

As the (100) silicon has a slight higher melting point, it tends to recrystallize first. A slowly cooled melt zone favors the formation of (100) silicon crystal. The elongated melt zone cool slowly along the scanning direction which forms a (100) silicon in the middle of zone along in the whole substrate. It will serve as seed for the subsequent ZMR process.

The re-crystallization zone is formed as a triangular shape 402 as shown in FIG. 9. The zone area has an apex 404 leading said scan area during scanning along scan direction 324. This can be achieved by means of three elongated areas 408a, 408b and 408c illuminated by the laser beams 322a. As shown in FIG. 9, preferably these areas 408a, 408b and 408c are in the shape of a line 408a parallel to said scan direction 324 followed along the scan direction by two lines 408b and 408c, one on each side of the scan direction and at an obtuse angle to the scan direction.

It works very much like a ship sailing through water. The tip or apex 404 of the melt zone 402 reaches the seed strip just created, it partially melts the seed layers as it is the biggest piece of crystal around. The small grain with higher surface energy will be melted first. Therefore, the seed strip becomes (100) lamellaes acting as seed for the crystal growth throughout the surface. The crystal grows along the scanning direction and also from center to side. As the recrystallization travels along the silicon layer on the substrate, the center will be recrystallized first as the melt zone reaches it first. It serves as the seed for the next as the melt zone travels along the scanning direction 324. However, it also serves as the seed to the adjacent areas perpendicular to the scanning direction, as it is melted right after the center is crystallized by the design of triangular melt zone. Therefore, the crystal is seeded from the center line. This is very much similar to the planar constricted method mentioned by Atwater et al., H. A., H. I. Smith, M. W. Geis, “Orientation Selection by Zone-Melting Silicon Films Through Planar Constrictions” Appl. Phy. Lett., pgs. 41, 747-749, (1982). However, this embodiment of the present invention has the advantage of not: having any pattern etched into the film.

As a result, a substantially single crystalline film can be obtained. This is especially truth for thick film. For relative thick films, the lateral growth dominates due to the high thermal conductivity of the silicon film compared to the substrate. This effect is enhancing even more when used a silicon powder. Silicon in powder form does not conduct heat well so the melt zone travels virtually from top to bottom, substantially suppressing the nucleation sites from the bottom interlace which does not have any long range order. Since the growth starts from the center to the sides along the scanning axis, the nucleation sites from the side will be greatly suppressed. Furthermore, the whole process is initially seeded from the beginning of the seed zone. There is no multiple nucleation site right from the start that would have created the multi-grains.

As a result, all the known mechanisms of creating multi-grain structures are suppressed. A substantially (100) single crystalline thin silicon film can be obtained for large substrates.

Texturing Substrate

Texturing can be done on the glass substrate instead of on the silicon material to avoid damage and surface defects, eliminating the need for defect etching and passivation process steps. The thick crystalline silicon layers ensured the high solar cell efficiency as in conventional crystalline silicon solar cells. Even higher panel efficiency can be realized due to 100% fill factor as oppose to the conventional 97%. Using large substrates bigger than standard panels is the ultimate wafer size scale. The cell processing cost is greatly reduced. All the materials and processes are well developed for the IC and solar industries with demonstrated reliability. As a result, the solar panels reliability produced by with this disclosed processing method brings about the same reliability of over 30 years as in the conventional crystalline silicon solar panels.

In solar cell applications, it is important to collect as much light as possible. One of the obvious applications is to applied AR coatings to the windows and solar cells to avoid glaring. However, it is very difficult to make AR coating work well for the whole hemisphere. As the sun move, the AR coating will not function properly.

Texturing is one common way to enhance the overall light collection efficiency lead to higher short circuit current. In the conventional solar cells, texture is created with a number of methods such as preferential etch, reactive ion etch (RIE) or by mechanical means to create textures on top of the silicon surface. See Damiani et al., “Development of RIE—Textured Silicon Solar Cells,” 28^{th} IEEE Photovoltaic Specialists Conference Record, pages 371-374 (2000) and Gerhards, et al., “Mechanically V-Texture Low Cost Multicrystalline Silicon Solar Cells with a Novel Printing Metallization,” 26^{th} IEEE Photovoltaic Specialists Conference Record, pgs. 43-46 and U.S. Pat. No. 4,137,123. A standard AR coating (SIN) reduce the weighted reflectance of a planar silicon surface from 35% to 10%; and a combination of AR coating and texturing reduce the weighted reflectance to as low as 39%. The texturing process creates surface damage that another etched step and a passivation step are needed.

Another embodiment is directed to a new method of creating texture on the substrate then molded into the subsequent silicon layer. Texture on glass substrate can be achieved from a number of ways such as etching or grounding. In fact, ground glass is readily available. Mechanical V-texture method gives a better control of surface texture. Since the damage is only to the substrate and not the photosensitive layer, these defects will not degrade the solar cell performance. The subsequent defect etch step is eliminated. A subsequent barrier/ARC layer isolates texture layer from the thick silicon layer. Therefore, the silicon layer will not experience any additional surface defect. Growing silicon directly on top of a substrate also eliminates one interface and reduces the index contrast on the combined one.

As a result, the embodiment enables significantly lower reflection than conventional panels, about 4% on glass air interface and 15% on the silicon/air interface. Considering the ARC and texturing, one can expected at least 6% low reflectance for the current invention.

The texture structure also act as an adhesion layer and buffer layer for stress build up along the silicon substrate interface. With the texture structure acting as an adhesion layer, it is much harder to delaminate and cause cracks on the film. The linear thermal expansion coefficient of the structure falls in between those of the substrate and the film, thus a perfect buffer layer.

Spraying

Instead of pouring or growing process for dispersing silicon powder described above, a uniform layer of polysilicon powder can be deposited uniformly with electrostatic aerosol deposition. It is a technique widely used in powder spray paint for furniture and appliance as described by Sergey Guskov from Nordson Corporation in “Electrostatic Phenomena In Powder Coating,” Technical Report PWR-96-1164, Nordson Corporation, 1996. In this technique, the silicon powder is mixed with a carrier gas such as Ar/H2 mixture. A partial pressure of H2 is used to reduce oxygen contact and native oxide on the silicon powder. As the powder passing through the nozzle, a corona gun at the nozzle charge up the powder particles. The electrostatic potential different between the corona gun and the ground behind the substrates attracts the powder particles onto the substrate. The fact the powder particles carried the same charges makes them wanted to be distributed evenly over the flat surface. The electrostatic charge as well as the high kinetic energy acquired by the charged particles in the high electric field would make the powder particles stick to the surface for many hours if not permanently. This property makes it easy to transport and process in different chambers.

It is common to install a commercially available powder recovery system (from vendors such as Nordson) to reuse the powder that is not attached to the substrate. The process is very clean that powder is only mix with high purity gas. There is no solvent or other contaminants introduced in to the powder material.

The used of aerosol deposition of silicon film have been disclosed. Silicon powder is deposited on a substrate and a silicon film is formed through high temperature annealing. In one embodiment of the present invention, aerosol deposition is used to create layered powder materials on low cost glass; the glass is then transferred into a vacuum chamber and heated to near glass transition temperature; a cw laser zone melt re-crystallization is performed to make the semiconductor layer crystalline.

The diffusion barrier layer comprising silicon dioxide and/or silicon nitride can also be formed by spraying. The texturing can also be formed by spraying silicon powder onto the glass substrate before the diffusion barrier layer is formed.

In summary,

1. That everything is within the confines of a solar panel.

2. That I do it on soda lime glass which has low softening point (about 560° C.)

3. That I heat from the bottom (which is an enabler for #2 above).

4. That the glass is textured to increase the efficiency of the solar panel.

5. That the glass is covered with a diffusion barrier layer.

6. That the diffusion barrier layer withstands high temperatures.

7. That there is no sodium diffusion from the glass into the silicon.

8. That the texturing is not destroyed as a result of high temperature.

9. That scanning is done by a line focus laser from the top—give typical powers scanning speed and why it melts the silicon at the bottom of the powder film.

10. That the end product is thick crystalline silicon on low cost glass.

11. That with the substrate of #10 above high efficiency solar cells can be made.

12. That the outcome of #10 may substitute thin 9 (˜1 micron thick) a-Si obtained by PECVD and offer a 3× improvement in efficiency.

13. That the outcome of #10 above may substitute thin (1 micron thick) tandem silicon by PECVD and offer a 3× improvement in efficiency.

While the invention has been described above by reference to various embodiments, it will be understood that changes and modifications may be made without departing from the scope of the invention, which is to be defined only by the appended claims and their equivalents.

1. An apparatus for converting sunlight to electricity, comprising:
a sheet of soda lime glass having a softening point not exceeding 600° C.; and
a layer of crystalline silicon over said sheet of soda lime glass, said layer having a thickness not less than about 5 microns, said layer having grains with grain size not less than about 100 microns.

2. The apparatus of claim 1, further comprising a diffusion barrier layer comprising silicon dioxide and/or silicon nitride between said crystalline silicon layer and said sheet.

3. The apparatus of claim 1, further comprising a layer of silicon dioxide and a layer of silicon nitride between said crystalline silicon layer and said sheet.

4. The apparatus of claim 1, further comprising an antireflection coating between said sheet and said layer of crystalline silicon, said coating being effective as a diffusion barrier to substantially prevent impurity diffusion between said crystalline silicon layer and said sheet when said sheet or said crystalline silicon layer is heated.

5. The apparatus of claim 1, further comprising an antireflection layer on a side of said crystalline silicon layer that is on the other side of said sheet.

6. The apparatus of claim 5, said antireflection layer comprising silicon dioxide or silicon nitride.

7. The apparatus of claim 5, said antireflection layer comprising a layer of silicon dioxide and a layer of silicon nitride.

8. A method for making a device for converting sunlight to electricity, comprising:
forming a film on a soda lime glass substrate;
dispersing silicon powder onto the film;
pressing a surface onto said silicon powder to form a layer of silicon powder on said film;
heating said substrate and film from below to a temperature not exceeding 600 degrees Celsius so that the soda lime glass substrate softens; and
while said substrate is in a softened state, heating by scanning a line focus laser beam or an elongated heater strip over a spatial sequence of adjacent elongated zones of the silicon powder consecutively so that the silicon powder in each of the zones melts and recrystallizes consecutively to form a layer of crystalline silicon with a thickness in the range of 5 to 100 micron over said film.

9. The method of claim 8, said dispersing comprising spraying or pouring silicon powder onto the film.

10. The method of claim 8, wherein said surface comprises a pattern of two dimensional structures on a flat base, so that said pressing imprints said pattern onto the layer of silicon powder.

11. The method of claim 10, said pattern comprising a two dimensional raised grid structure, so that a two dimensional array of raised areas with trenches between adjacent areas is formed on a surface of said layer of silicon powder for stress relief and solar cell definition.

12. The method of claim 8, further comprising supplying said line focus laser beam by means of at least one laser diode bar.

13. The method of claim 8, wherein said scanning occurs when said substrate, the layer of silicon powder and said film are in a vacuum or reduced pressure inert atmosphere.

14. The method of claim 8, wherein a wavelength of radiation in said line focus laser beam is substantially 780 or 980 nm.

15. The method of claim 8, wherein said substrate and film are heated to a temperature in the range of 500 to 600 degrees Celsius.

16. The method of claim 8, further comprising creating an uneven surface texture on said substrate before said film is formed on the soda lime glass substrate.

17. The method of claim 16, wherein said creating or forming includes a spraying process.

18. The method of claim 8, said creating including spraying silicon powder on said substrate.

19. The method of claim 8, wherein said dispersing disperses silicon powder of average particle size in the range of 1-50 microns.

20. The method of claim 8, wherein said film comprises alternate layers of silicon dioxide and silicon nitride.

21. The method of claim 8, further comprising creating an anti-reflection coating on said glass substrate on the other side of said film, said coating comprising a layer of silicon dioxide and/or a layer of silicon nitride.

22. The method of claim 8, said dispersing comprising iodine transport deposition of silicon onto the film.

23. A method for making a device for converting sunlight to electricity, comprising:
forming a film on a soda lime glass substrate;
dispersing silicon powder onto the film;
pressing a flat surface onto said silicon powder to form a layer of silicon powder on said film;
heating said substrate and film from below to a temperature not exceeding 600 degree Celsius so that the soda lime glass substrate softens;
while said substrate is in a softened state, heating by scanning a line focus scanning laser beam or a heater strip over a spatial sequence of adjacent zones of the silicon powder consecutively so that the silicon powder in each of the zones melts and recrystallizes consecutively to form a layer of crystalline silicon with a thickness in the range of 5 to 100 micron over said film, said laser beam or heater strip scanning and heating a triangular area of the layer of silicon powder, said area having an apex leading said scan area during scanning.

24. The method of claim 23, wherein the laser beam or heater strip scans along a scan direction, said area having a shape of a line in said scan direction followed in the scan direction by two lines, one on each side of the scan direction and at an obtuse angle to the scan direction.
